(19) United States
(12) Patent Application Publication
(10) Pub. No.: US 2024/0142530 A1
(43) Pub. Date: May 2, 2024

(54) SYSTEM AND METHOD TO CHARACTERIZE THE PERFORMANCE OF ELECTRICAL STORAGE SYSTEMS

(71) Applicant: Tektronix, Inc., Beaverton, OR (US)

(72) Inventors: K T Anurag, Bengaluru (IN); Krishna N H Sri, Bengaluru (IN); Madhusudan Acharya, Bengaluru (IN); P E Ramesh, Bengaluru (IN)

(21) Appl. No.: 18/385,318

(22) Filed: Oct. 30, 2023

(30) Foreign Application Priority Data
Nov. 1, 2022 (IN) 202221062332

(51) Int. Cl. G01R 31/389; G01R 31/367; G01R 31/3842

(52) U.S. Cl. CPC G01R 31/389; G01R 31/367; G01R 31/3842

(57) ABSTRACT

A testing system for performing Electrochemical Impedance Spectroscopy on a Unit Under Test (UUT) includes a function generator configured to apply a plurality of frequency components combined in a single burst or broadband stimulus to the UUT, and an oscilloscope having one or more processors configured to measure an amplitude ratio and phase difference between a voltage and a current of the UUT at a plurality of frequencies after the single burst or broadband stimulus of frequency components has been applied, generate a Nyquist plot of impendence values in both real and imaginary axes from the measured phase difference, and present the Nyquist plot at an output of the oscilloscope. Methods of operation are also described.

### CROSS-REFERENCE TO RELATED APPLICATIONS

This disclosure claims priority under 35 U.S.C. § 119 to Indian Provisional Patent Application No. 202221062332, filed Nov. 1, 2022, titled “SYSTEM AND METHOD TO CHARACTERIZE THE PERFORMANCE OF ELECTRICAL STORAGE SYSTEMS,” the disclosure of which is incorporated herein by reference in its entirety.

### TECHNICAL FIELD

This disclosure relates to energy storage systems and, more particularly, relates to an electrochemical impedance spectroscopy system and method for determining the performance of electrical storage systems.

### BACKGROUND

There is growing demand for generating and storing electricity for domestic consumption using non-biomass fuels. This increased demand is for domestic consumption, through power grids, as well as for automotive applications. Batteries, and, in particular, rechargeable batteries, are becoming a common method for energy storage in the fields of electricity generation (e.g., photovoltaic (PV) power systems), domestic usage, microgrids and automotive applications (e.g., electric and hybrid electric vehicles). One issue with rechargeable batteries in the above-mentioned applications is that they undergo various degradation processes over time. This degradation results in reduction of performance, decrease in capacity and/or power, and other operating factors.

Various monitoring methods and systems are in place for monitoring parameters of the energy storage systems and determining the overall State of Health (SOH) of the energy storage systems. Some examples of present monitoring methods include Coulomb counting, AC internal resistance, weld measurements, voltage monitoring methods, and state of charge (SOC) algorithms, etc. These existing tests, however, may produce errors due to internal self-discharge currents and other performance issues. Yet other battery analysis tools use very expensive tools such as X-ray microscopy and dedicated, special purpose instruments, which are also expensive. Further, traditional measuring equipment such as source measurement units (SMU's) or any other dedicated instruments fail to account for the voltage and current waveforms of the energy storage systems in a continuous mode, making it difficult to adequately characterize battery status as well as to adequately perform design verification for new battery cells and modules.

Embodiments according to the disclosure address these and other limitations in the state of the art measuring systems.

### BRIEF DESCRIPTION OF THE DRAWINGS

FIGS. 1A and 1B, represent simplified circuit diagrams for performing analysis of frequency response of the energy storage system, in accordance with an embodiment of the present disclosure.

FIG. 2A represents an equivalent circuit model corresponding to the energy storage system, in accordance with an embodiment of the present disclosure.

FIG. 2B represents a graphical representation depicting the frequency response of the equivalent circuit model of FIG. 2A, in accordance with an embodiment of the present disclosure.

FIGS. 3A and 3B respectively illustrate a graphical representation of impedance and phase plots generated for the energy storage system, in accordance with an embodiment of the present disclosure.

FIG. 4 illustrates a graphical representation of Nyquist plot at a different temperature, in accordance with an embodiment of the present disclosure.

FIGS. 5A and 5B respectively illustrate graphical representations depicting Nyquist plot of the energy storage system in normal condition and degraded condition, in accordance with an embodiment of the present disclosure.

FIG. 6 illustrates a Nyquist plot depicting circuit parameters of the energy storage system, in accordance with an embodiment of the present disclosure.

FIG. 7 illustrates an output screen of a user interface that may be displayed on a test and measurement instrument depicting a controlled loop analysis illustrating both phase and gain curves, along with a result table and time-domain waveform view, according to embodiments of the present disclosure.

FIG. 8 is a simplified circuit diagram for performing analysis of frequency response of the energy storage system including artificial intelligence analysis portion, in accordance with another embodiment of the present disclosure.

FIG. 9 is an example of a sweep frequency stimulus in burst or broadband mode used to generate multiple frequency components stitched into a single burst for applying to a Unit Under Test (UUT) according to embodiments of the present disclosure.

FIG. 10 illustrates graphical representations depicting Nyquist plot of the energy storage system under fully charged condition of a UUT, in accordance with an embodiment of the present disclosure.

### DETAILED DESCRIPTION

In the following description, for purposes of explanation, specific details are set forth in order to provide an understanding of the present disclosure. It will be apparent, however, to one skilled in the art that the present disclosure may be practiced without these details. One skilled in the art will further recognize that embodiments of the present disclosure, some of which are described below, may be incorporated into several systems.

Embodiments according to this disclosure are directed to a system and method for characterizing the performance of electrical storage systems. In particular, the disclosed systems allow a user to perform Electrochemical Impedance Spectroscopy (EIS) in a manner never before possible, using devices commonly found in a testing laboratory, as described in detail below.

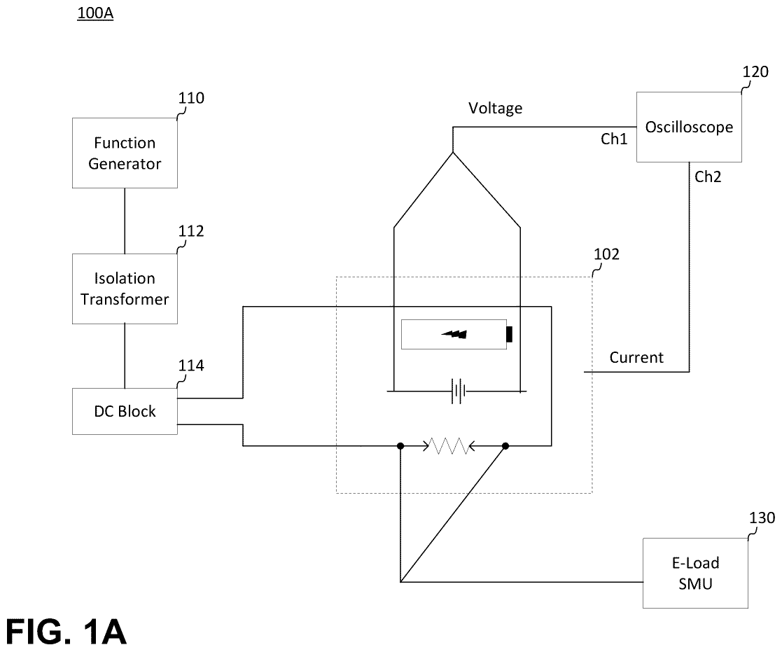

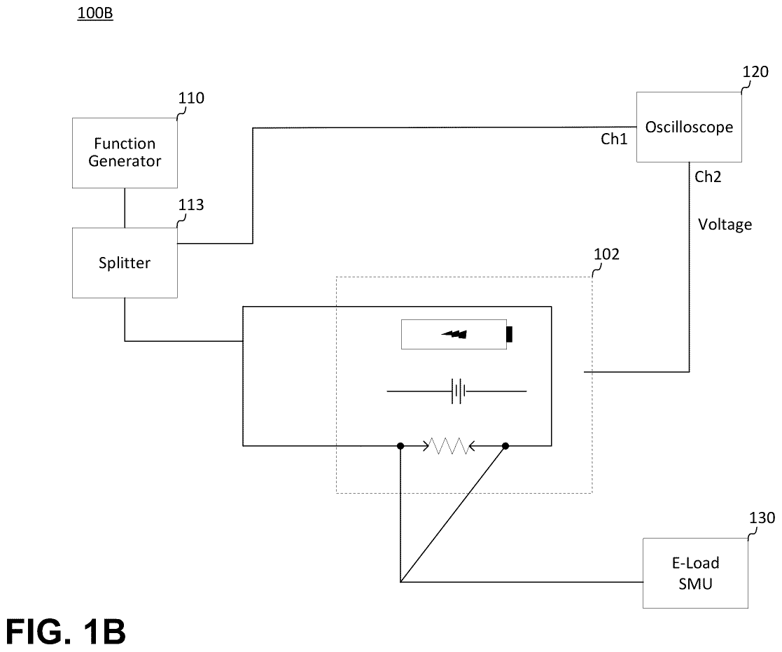

FIGS. 1A and 1B, are simplified block circuit diagrams for performing analysis of frequency response of an energy storage system, in accordance with embodiments of the present disclosure. These circuit diagrams represented in FIGS. 1A and 1B are configured to implement EIS techniques to determine the performance of an energy storage system based on analyzing the frequency response.

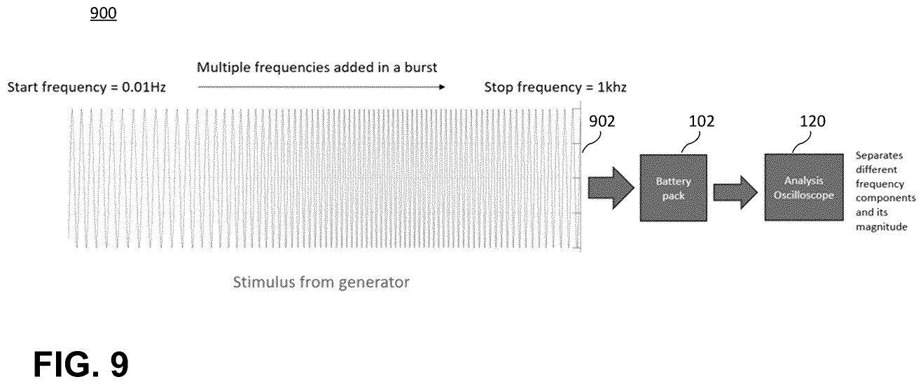

As shown in FIG. 1A, a circuit diagram 100A is illustrated for phase measurement of an energy storage system 102. In this figure the energy storage system 102 is a test fixture including a battery, such as a rechargeable battery, and load resistor, and is referred to as a Unit Under Test (UUT). The UUT 102 may be a single cell or a battery pack, depending on the particular test. Details of the load resistor are described below. The circuit diagram 100A includes multiple hardware components that together may be operated to implement one embodiment of an EIS testing system. The EIS testing system 100A of FIG. 1A includes a function generator 110 configured to generate multiple waveforms with varying pulse widths, for example from 20 ns to 150 μs, in a predefined time. In one embodiment these pulses are generated in a burst mode, where all of the generated frequencies are applied to UUT 102 in a short amount of time, e.g., less than 1 second. In embodiments, multiple frequency points are generated and stitched as a burst stimulus and provided to the UUT 102 as an input. In one example, fifty separated frequencies spanning 1 Hz through 1 KHz are applied to the UUT 102 within one millisecond. In other embodiments, pulse frequencies applied to the UUT 102 may span smaller or larger frequency spans. An example of the burst mode frequency stimulus is described in more detail with reference to FIG. 9 below.

Referring back to FIG. 1A, an oscilloscope 120 is a test and measurement device that measures qualities of signals it receives at one or more inputs. As described in detail below, the oscilloscope 120 may include instructions or software for performing the measurement and analysis. In an example, the oscilloscope 104 may be a mixed signal oscilloscope (MSO) configured to combine the analog channels of a traditional oscilloscope with additional logic channels of a logic analyzer, such as an MSO available from Tektronix, Inc. of Beaverton, Oregon. Sample rates for the oscilloscope 120 may be in the range of 100 KHZ to multiple GHz. The oscilloscope 120 includes one or more computer processors structured to operate on stored instructions from a memory to perform the testing and measuring functions and operations described herein, including generating graphs, plots, and lists of data useful for implementing embodiments according to the disclosure.

An isolation transformer 112 is configured to provide electrical separation or isolation between the frequency generator and the test system prior to taking measurements. The isolation transformer 112 acts as a safety device to prevent a current path between the function generator and the UUT 102, and also reduces transients and harmonics in the testing system. For example, if the UUT 102 is isolated, and the oscilloscope 120 is connected to any other conducting part, then that position becomes ground referenced. In this scenario, without the isolation transform 112, direct contact with the UUT 102 may result in shocks. Therefore, including the isolation transform 112 provides additional safety to the testing system 100A. A DC block 114 operates to block DC signals or offsets for testing. Finally, an electronic load, such as a Source Measuring Unit (SMU) 130 may be used to produce specific load signals for the UUT 102 in its testing setup.

Testing environment 100B of FIG. 1B illustrates a testing environment for taking an impedance measurement of the UUT 102. In this testing environment 100B, a splitter 113 divides the signal from the function generator 110 and provides a copy of what is being applied to the UUT 102 directly to one channel of the oscilloscope 120. Another channel of the oscilloscope 120 is directly coupled to the UUT 102.

In conjunction, the components of the testing environments 110A and 100B of FIGS. 1A and 1B are configured to measure phase and impedance (Z) of the UUT 102, as described in more detail below.

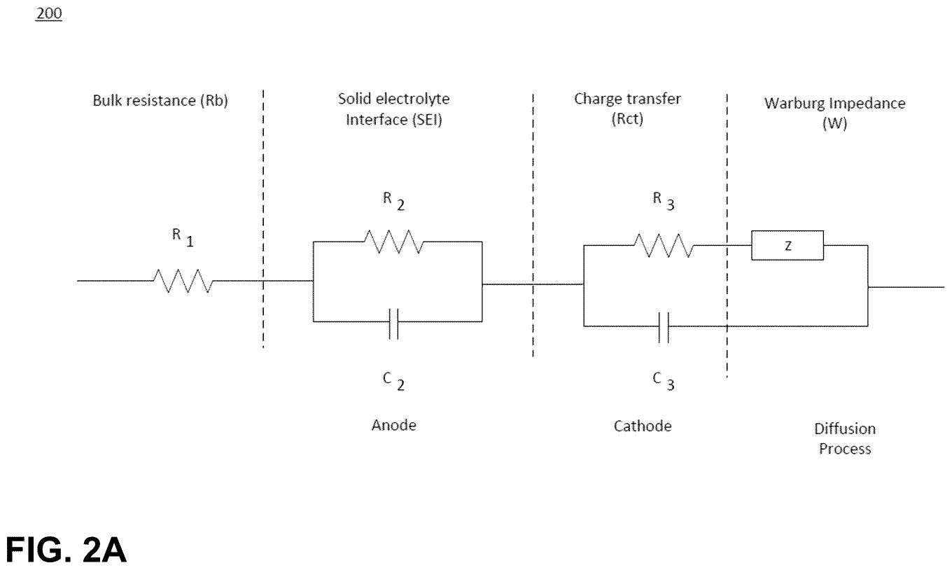

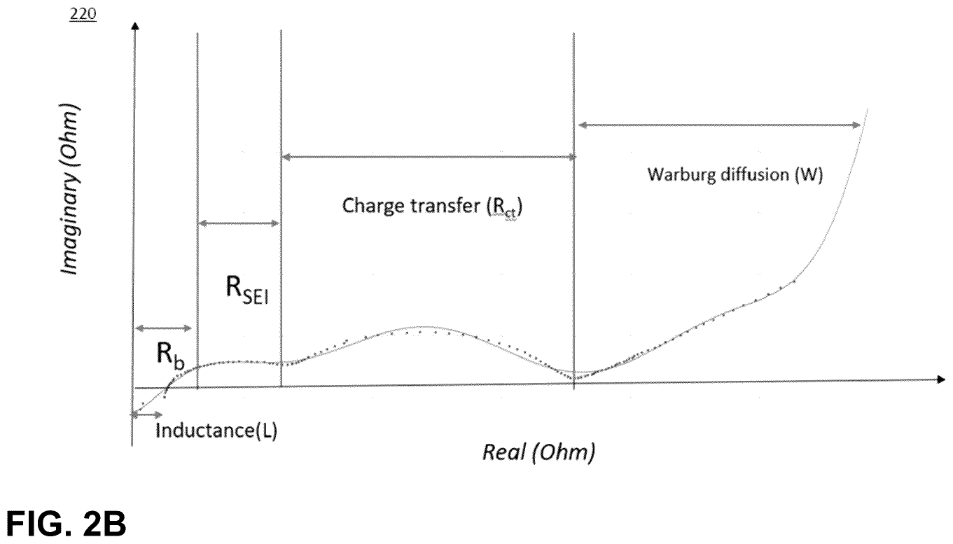

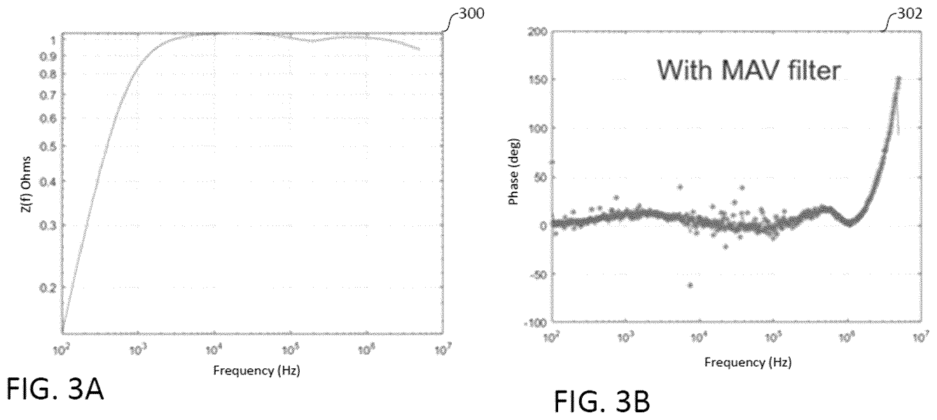

As briefly described above, the testing environments implementing the EIS method facilitate analysis of the impedance of the UUT 102 over a specific range of frequencies. Thus, the internal electrochemical processes of the UUT 102 at different time constants can be determined. More specifically, the oscilloscope 120 in the testing environments 110A and 110B records the amplitude ratio and the phase difference between the voltage and the current of the UUT 102 after the burst of frequencies has been applied to it. To that effect, characterizing the impedance associated with the UUT 102 at multiple frequencies is possible. In order to determine the aforementioned parameters, a small AC signal is applied over a wide frequency range, as described above, and the response is measured. As described in detail below, measuring the magnitude and phase of the impedance associated with the UUT 102 allows embodiments according to this disclosure to generate impedance and Bode plots, which are described below with reference to FIGS. 3A and 3B. Further, measuring the magnitude and phase of the impedance allows embodiments according to this disclosure to generate a Nyquist, or impedance, plot, by determining the real and imaginary portions of the impedance, which is described with reference to FIG. 2B.

Embodiments according to the disclosure use circuit models to represent the frequency response of the energy storage system (UUT) 102. For example, the UUT may be a Lithium-ion battery, a Nickel-Cadmium battery, an Alkaline Battery, or a Sodium-ion battery, among other battery types. An equivalent circuit model of the lithium-ion battery is represented in FIG. 2A, which can be used for performing the tests to determine the parameters indicative of the performance of the lithium-ion battery. Other battery types may have the same or different equivalent circuit models. Although examples in this disclosure are described with reference to a UUT being a Lithium-ion battery, embodiments may be used with any type of battery as the UUT.

Referring to FIG. 2A in conjunction with FIGS. 1A and 1B, an equivalent circuit model 200 corresponding to the lithium-ion battery (or the UUT 102) is designed to help analyze the measured Nyquist plot of the UUT. As shown, the circuit model 200 of the UUT 102 includes four main resistive and reactive components. The components of the circuit model 200 includes a bulk resistance (Rb) component, represented as ‘R1’, a solid electrolyte interface (R_{SEI}) including a combination of a resistor represented as ‘R2’ and a capacitor represented as ‘C2’ connected in parallel, a charge transfer resistance (Rct) component including a combination of a resistor represented as ‘R3’ and a capacitor represented as ‘C3’ connected in parallel, and a Warburg impedance (W) component represented as ‘Z’. It is to be noted that all the components of the circuit model 200 are connected in a series connection. Further, the components of the circuit model 200 define operating characteristics of the UUT 102 at different frequencies, which will be explained with reference to FIG. 2B.

In one example, the impedance (Z_{T}) of the circuit model 200 can be computed using the following equation (Eq. 1):

Z_{T}=R1+R2/(1+jω*C2*R2)+R3*Z/((R3+Z)+jω*C3*R3*Z) (Eq. 1)

Referring now to FIG. 2B in conjunction with FIG. 2A, a graphical representation 220 is illustrated. The graphical representation 220 in FIG. 2B is a Nyquist plot representing the impedance response of the circuit model 200 of FIG. 2A. It is to be noted that the semicircle portions are usually attributed to certain processes using their characteristic frequency. Thus, the transition from one dominant process to a different characteristic process can be visualized in the spectra through changes of the angle and amplitude. Moreover, the chemical parameters associated with the circuit model 200 of the UUT 102 may be extracted from the Nyquist plot. In particular, the chemical parameters are determined based on the semi-circular regions of the Nyquist plot, and, further, the resistance of the UUT 102 may be determined by taking the mean value on the real axis. The parameters of the circuit model 200 computed based on the semi-circular regions are as follows:
Region ‘Rb’: this region corresponds to the behavior of the circuit model 200 due to non-zero ohmic resistance, i.e., resistance ‘Rb’. Further, ‘Rb’ is total resistance of the electrolyte, separator, and electrodes and is significantly related to the overall state of health (SOH) of the UUT 102. It is to be noted that, with decreasing frequency, the spectrum of the non-zero ohmic resistance intersects the real impedance (Z) axis at high frequency. This region corresponds to the first portion of the circuit model 200 of FIG. 2A.
Region ‘R_{SEI}’: this region is a first semicircular region in the Nyquist plot and is associated with the generation of the interfacial layer deposited on the electrode. It corresponds to the second portion of the circuit model 200 of FIG. 2A.
Region ‘Rct’: this region represents a second semicircle region in the Nyquist plot and is related to the kinetics of the electrochemical reaction, which is changed by the surface coating, phase transition, band gap structure or particle size. It corresponds to the third portion of the circuit model 200 of FIG. 2A.
Region of Warburg impedance (W): this region conforms to a relatively straight line of the Nyquist plot, and is related to the diffusion of lithium ions. This region corresponds to the fourth portion of the circuit model 200 of FIG. 2A.

The behavior of the circuit model 200 may be in the negative imaginary impedance axis at high frequencies due to the inductive effects associated with the circuit model 200. In general, the impedance of the real and imaginary axis corresponds to:

Zreal=Z*cos(Φ):R(resistance Rb) (Eq. 2)

Zimg=Z*sin(Φ):C(capacitance)+L(inductance) (Eq. 3)

Further, the State of Charge (SoC) of the circuit model 200 can be determined as ratio of the amount of energy stored in the UUT 102 to the nominal rated capacity. In an example, the SoC is computed using the following equation (Eq. 4):

SOC=∫Idt (Eq. 4)
where I is the battery current integrated from 0 to the charging time.

Furthermore, the State of Health (SOH) of the UUT 102, based on the circuit model 200, may be determined as the ratio of maximum releasable capacity to the nominal rated capacity.

The UUT 102 may be dynamically operated during testing, such as by the e-load/SMU 130 (FIGS. 1A/1B) to follow load demands, and various slow and fast processes take place in parallel in the battery during such dynamic operation. As such, these processes interfere with each other and yield a complex dynamic behavior, which is observable by the oscilloscope 120 (FIG. 1A/1B) in the interplay of the current and voltage versus time. Further, fast dynamic processes regulate the response within micro and milliseconds, whereas responses related to slow processes such as solid diffusion are observable only after longer response times. Thus, the resulting overall dynamic response of the UUT 102 to a certain change in voltage or current is thus characteristic for the processes in its interior and, for a given design of a battery, its operating point, state of charge, and state of health. Therefore, dynamic signals gathered by the testing systems 100A and 100B of FIGS. 1A and 1B are considered for analyzing the SoH of the UUT 102.

As mentioned above, the measurements made by the testing systems 100A and 100B of FIGS. 1A and 1B may be used to generate one or more Bode plots of the frequency response of the UUT 102 during testing. In an embodiment, the phase measurement at different frequencies from Bode plot is generated by using following equation (Eq. 5):

Phase@swept frequency=FFT((Phase(output voltage)−Phase(output current)) (Eq. 5)

### Wherein,

Control Loop Response computes phase difference between Input to Output source at each frequency within the measured band, where frequency spans from 1 Hz to 40 MHz,
FFT is Fast Fourier Transformation,
Phase is the time shift between the input and output signals, and
Phase (Output voltage and current) are the output voltage and current of the UUT 102.

FIG. 3B illustrates a Bode plot of phase using a moving average (MAV) filter.

Regarding impedance measurements, in an embodiment, impedance (Z) is computed as source gain magnitude ratio by using the following equation (Eq. 6):

Z=(G/(1−G)) (Eq. 6)

Where G is gain magnitude,
Further, G in dB=

Log₁₀((Output voltage)−(AFG Direct(input)voltage)) (Eq. 7)

FIG. 3A illustrates a graphical representation of an impedance plot generated for a particular example of UUT 102, in accordance with an embodiment of the present disclosure. In an example, the energy storage system 102 may include a 6V or 12V lithium-ion battery charged to their half capacity.

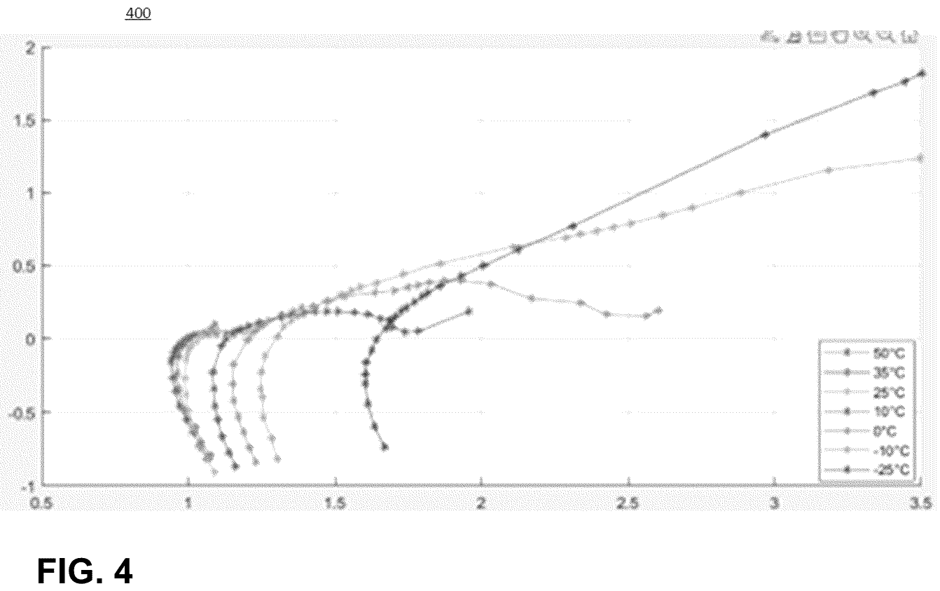

FIG. 4 illustrates an example Nyquist plot generated for a particular UUT 102 (FIGS. 1A/2A) at various temperatures, in accordance with an embodiment of the present disclosure. In particular, the UUT 102 was subject to various temperatures spanning from −25° C. to 50° C. across seven intervals. The UUT 102 was measured by injecting broadband frequencies in a burst mode into the UUT 102 as described above, and the responses measured by the oscilloscope 120, also as described above.

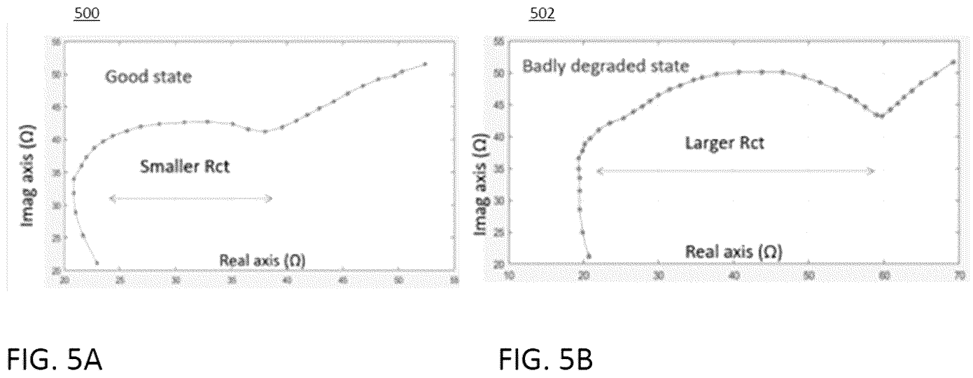

FIGS. 5A and 5B illustrate how the Nyquist plot for various UUTs 102 communicates parameters of the units under test. In particular, FIG. 5A illustrates a Nyquist plot of a rechargeable battery in a normal or good condition, while FIG. 5B illustrates a Nyquist plot of a rechargeable battery in a poor or degraded state. Inspection of the two Nyquist plots in FIGS. 5A and 5B show that there is a significant difference in the charge transfer resistance (Rct) between the normal battery condition illustrated in FIG. 5A and the degraded battery condition battery illustrated in FIG. 5B. More specifically, the resistance ‘Rct’ in FIG. 5B for the degraded battery is of higher magnitude than the normal battery.

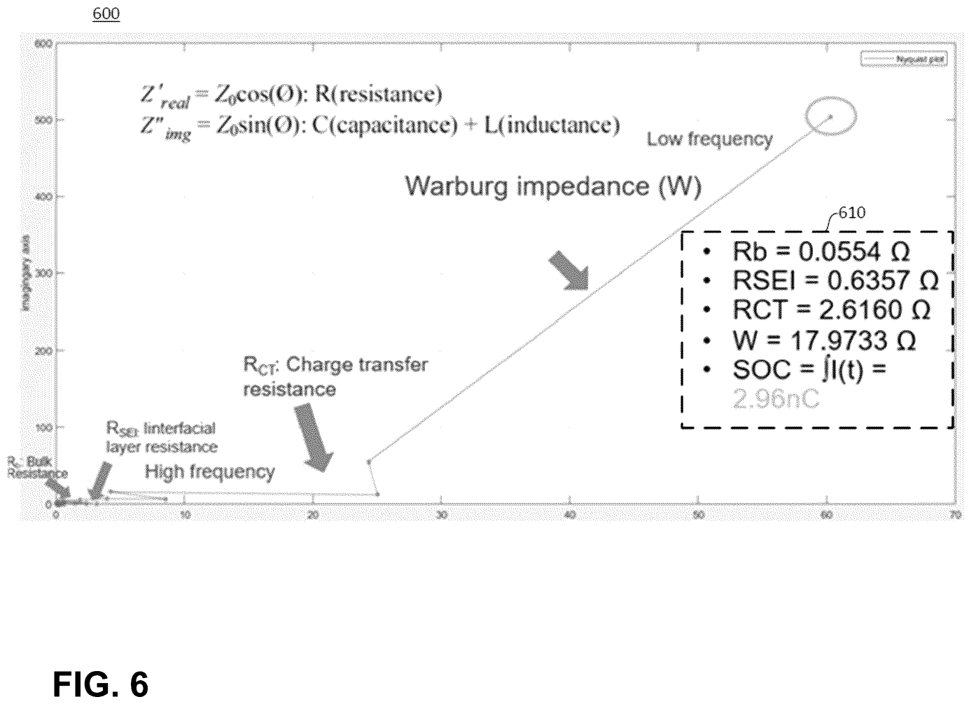

After one or more Nyquist plots are generated for a UUT as shown in FIGS. 4, 5A, and 5B, the Nyquist plot may be analyzed and broken down into separate regions in accordance with the circuit parameters as discussed above with reference to FIG. 2B. In particular, embodiments according to the disclosure create an output Nyquist phase plot 600, such as the one illustrated in FIG. 6 for presenting on a screen or output of the oscilloscope 120 of FIGS. 1A and 1B.

The output Nyquist plot 600 differs from the Nyquist plots illustrated in FIGS. 4, 5A and 5B in that the Nyquist plot 600 includes only a few test point, as the test was run only for a short time. As described above, the Nyquist plot 600, like the previous Nyquist plots, are generated using the real and imaginary impedances calculated using Equations 2 and 3 set forth above, which relate to the capacitance and inductance values of the circuit. Even when the Nyquist plot includes only a few values, the Nyquist plot 600 still clearly illustrates the four separate zones of the model circuit (Rb, R_{SEI}, R_{CT}, and W). Also, an inset box 610 of scalar values generated from the Nyquist phase plot 600 may be illustrated as well. The scalar values may be generated by taking the average value of the values plotted in the Nyquist phase plot 600 for each of the four zones described with reference to FIGS. 2A and 2B. Thus the value Rb is determined by taking the average of the Nyquist plot values in the bulk resistance (Rb) zone, the value RSEI is determined by taking the average of the Nyquist plot values in the solid electrolyte interface (SEI) zone, the RCT value is determined by taking the average of the Nyquist plot values in the charge transfer zone, and the Warbug Impedance W is determined by taking the average of the Nyquist plot values in the Warburg Impedance zone. Finally, the state of charge SOC is determined using Equation 4, with an integration of current during a period of charging times.

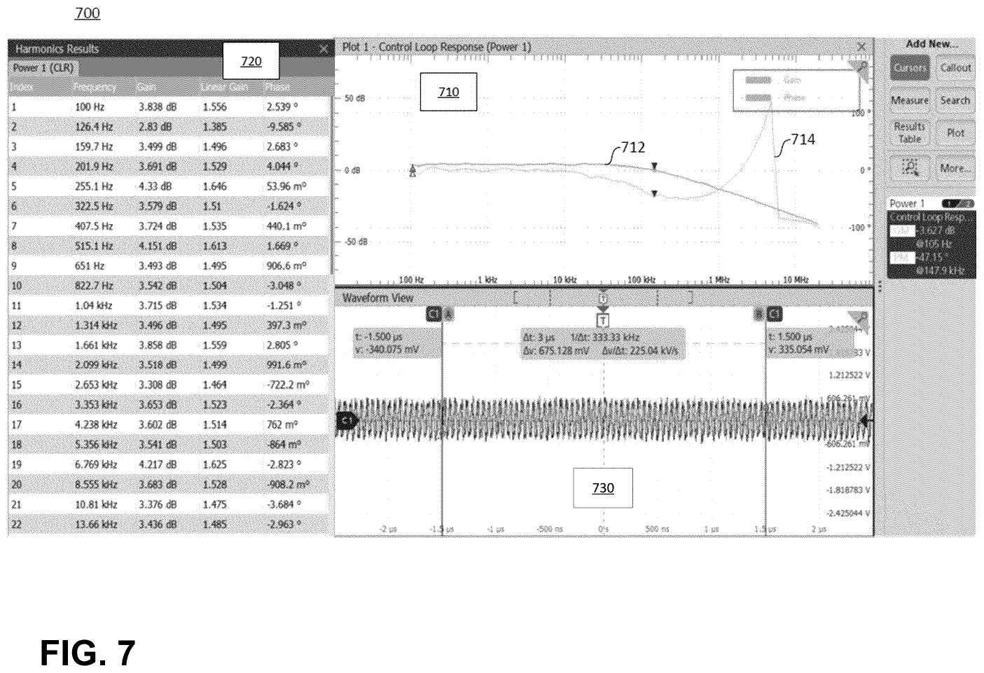

FIG. 7 is a screen diagram of an example display screen 700 that may be shown on the oscilloscope 120 (FIGS. 1A/1B) during testing of the UUT 102. The display screen 700 includes three main sections. A section 710 illustrates a control loop analysis, or Bode plot, illustrating gain 712 and phase 714 values over a range of frequencies illustrated in section 720. Although section 720 illustrates only 22 values, additional values are present and available by scrolling. Note that the horizontal axis of section 710 is illustrated in log scale, although such a scale is not required. This measurement illustrated in section 720 is performed by sweeping discrete frequencies from the frequency generator individually. Although a similar Bode plot may be generated when using the burst mode of applying frequencies, this embodiment illustrated in section 720 provides details of the gain and phase values at all frequencies swept between a start and stop range. The section 730 illustrates the same outputs as the Bode plot of 730 except in a time domain, in this case between two cursers set at −1.500 μs and +1.500 μs. The information phase and gain information in the time domain of section 720 allows the designer to visualize if there are any glitches in the waveform, or whether the shape of the waveform is very noisy. For example, if the waveform in the section 720 lacks sinusoidal values or if there are openings between the gain margin (GM) and phase margins (PM).

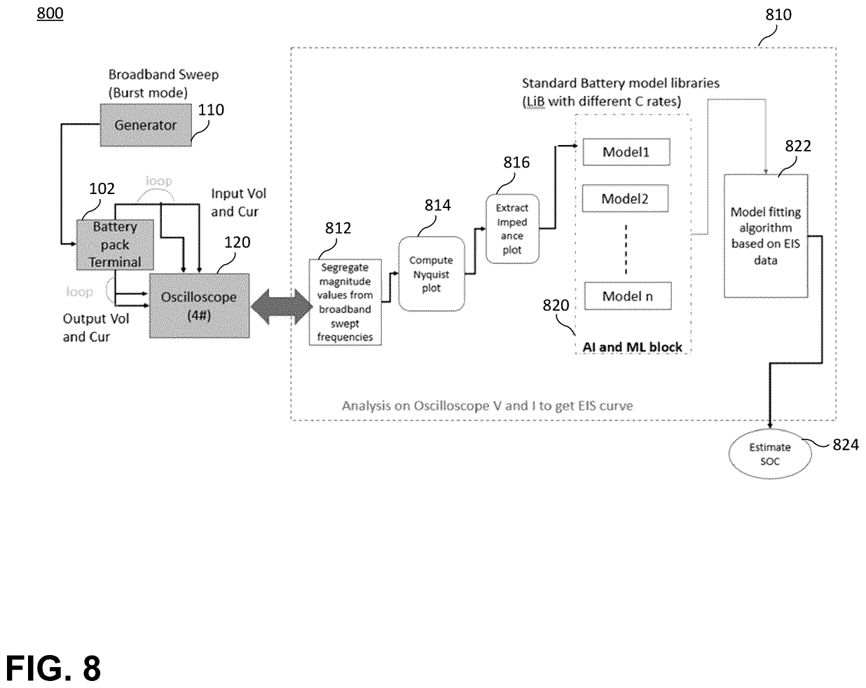

FIG. 8 illustrates another simplified circuit diagram 800 for performing analysis of frequency response of the energy storage system according to embodiments. In the circuit 800, the general components illustrated in FIGS. 1A and 1B are present, with additional information provided in a processing block 810 describing additional processes that perform testing of the UUT according to embodiments. A block 812 is performed on the oscilloscope output, after the burst mode of frequencies has been applied to the UUT 102 by the frequency generator 110. A function 812 of the processing block 810 performs a post-processing function by searching each frequency component that was applied during the burst mode in the FFT domain. This search and separation filters the results. For each identified frequency component, the magnitude of the highest energy value is extracted and stored. A process 814 generates the Nyquist plot as described above, by plotting impedance values on both the real and imaginary axes. Next the impedance plot is extracted in an operation 816 as described above with reference to FIG. 3A. Machine learning may be applied to the process in operations 820, 822, and 824. First, a large number of plots of standard battery libraries of various known states of health are ingested in the operation 820 as a training set of base libraries. Then, the particular plot generated by embodiments for the UUT 102 is compared to the training set and model fitting is performed based on the generated EIS data. Finally, the closest match, or matches are used to make a prediction of the battery life of the just-measured UUT and the results output in an operation 824. This matching helps to characterize battery performance and aging, and can predict the life of the UUT much better than previous methods.

FIG. 9 graphically illustrates how the broadband frequencies are applied to the UUT in a burst mode. With reference to FIG. 9 along with FIGS. 1A and 1B, the frequency generator 100 generates a burst or broadband mode of a group of frequencies 902 and applies it to the UUT 102 in a single burst. In the diagram 900 of FIG. 9, the starting frequency applied to the UUT 102 begins at 0.01 Hz and ends at 1 kHz. Applying this composite of frequencies to the UUT 102 in a short amount of time is much faster than the previous method of sweeping through various frequencies individually. The frequencies in the group of frequencies 902 generally include at least 10 points per decade and may include up to 100 points per decade. The number of points per decade affects the performance of the EIS. With the range of frequencies described above, 10 points per decade yields approximately 55-60 individual frequency points in the group of frequencies 902. Of course, other

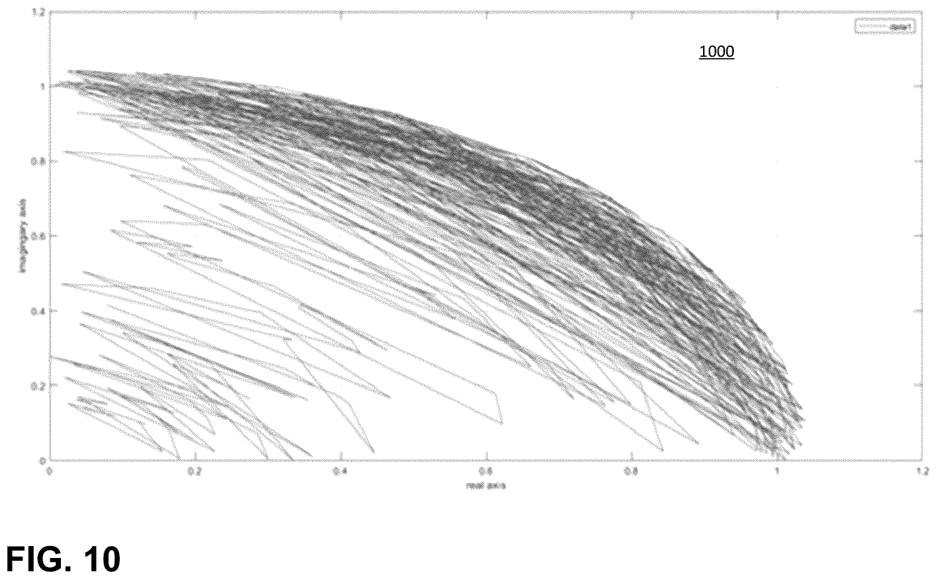

FIG. 10 illustrates graphical representations depicting a Nyquist plot 1000 of a battery (or the UUT 102) under fully charged condition, in accordance with an embodiment of the present disclosure. This Nyquist plot 1000 differs from the previous Nyquist plots illustrated in FIGS. 5A, 5B, and 6 in that the separate zones seen in these previous Nyquist plots are not present in the plot 1000. It is therefore obvious by observation of the plot 1000 that the UUT 102 under fully charged condition does not exhibit true diffusion.

The foregoing description of the invention has been set merely to illustrate the invention and is not intended to be limiting. Since modifications of the disclosed embodiments incorporating the substance of the invention may occur to person skilled in the art, the invention should be construed to include everything within the scope of the invention.

The terms and words used in the following description and claims are not limited to the bibliographical meanings but are merely used by the inventor to enable a clear and consistent understanding of the invention. It is to be understood that the singular forms “a,” “an,” and “the” include plural referents unless the context clearly dictates otherwise.

References in the specification to “one embodiment” or “an embodiment” mean that a particular feature, structure, characteristic, or function described in connection with the embodiment is included in at least one embodiment of the invention. The appearances of the phrase “in one embodiment” in various places in the specification are not necessarily all referring to the same embodiment.

It should be noted that the description merely illustrates the principles of the present invention. It will thus be appreciated that those skilled in the art will be able to devise various arrangements that, although not explicitly described herein, embody the principles of the present invention. Furthermore, all examples recited herein are principally intended expressly to be only for explanatory purposes to help the reader in understanding the principles of the invention and the concepts contributed by the inventor to furthering the art and are to be construed as being without limitation to such specifically recited examples and conditions. Moreover, all statements herein reciting principles, aspects, and embodiments of the invention, as well as specific examples thereof, are intended to encompass equivalents thereof.

Aspects of the disclosure may operate on particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a testing system for performing Electrochemical Impedance Spectroscopy on a Unit Under Test (UUT), the system including a function generator configured to apply a plurality of frequency components combined in a single burst or broadband stimulus to the UUT; and an oscilloscope having one or more processors configured to measure an amplitude ratio and phase difference between a voltage and a current of the UUT at a plurality of frequencies after the single burst or broadband stimulus of frequency components has been applied, generate a Nyquist plot of impendence values in both real and imaginary axes from the measured phase difference, and present the Nyquist plot at an output of the oscilloscope.

Example 2 is a testing system according to Example 1, further comprising a load-varying device configured to apply at least two different loads to the UUT, and in which the one or more processors of the oscilloscope is further configured to measure an amplitude ratio and phase difference between a voltage and a current of the UUT at a plurality of frequencies after the single burst of frequency components has been applied for at least two different load values applied to the UUT, generate a Nyquist plot of impendence values in both real and imaginary axes from each of the at least two measured phase difference, and produce the Nyquist plots on a single image at the output of the oscilloscope.

Example 3 is a testing system according to any of the preceding Examples, in which the plurality of frequency components in the single burst comprises at least 20 individual frequency points spanning a specific frequency range based on qualities of the UUT.

Example 4 is a testing system according to Example 3, in which the frequency range spans between 0.01 Hz and 1 KHZ.

Example 5 is a testing system according to any of the preceding Examples, in which the plurality of frequencies used for measuring the amplitude ratio and phase difference is based on qualities of the UUT.

Example 6 is a testing system according to Example 5, in which the plurality of frequencies used for measuring the amplitude ratio and phase difference spans from 1 Hz to 40 MHz.

Example 7 is a testing system according to Example 1, in which the one or more processors of the oscilloscope are structured to generate a gain plot and a phase plot of the measured amplitude and phase difference between the voltage and the current of the UUT at the plurality of frequencies, and present the gain plot and the phase plot on the output of the oscilloscope.

Example 8 is a testing system according to any of the preceding Examples, further comprising determining a state of charge of the UUT by model fitting the Nyquist plot against a plurality of Nyquist plots of other UUTs having known states of charge, at least two of the plurality of Nyquist plots having different input voltages and temperature conditions than others in the plurality of Nyquist plots.

Example 9 is a testing system according to any of the preceding Examples, in which the one or more processors of the oscilloscope are structured to output scalar values representing one or more zones of the Nyquist plot.

Example 10 is a testing system according to Example 9, in which the scalar values include values for one or more of bulk resistance, solid electrolyte interface, charge transfer, and Warburg impedance.

Example 11 is a method for performing Electrochemical Impedance Spectroscopy on a Unit Under Test (UUT), including applying a plurality of frequency components combined in a single burst or broadband stimulus to the UUT, measuring an amplitude ratio and phase difference between a voltage and a current of the UUT at a plurality of frequencies after the single burst or broadband stimulus of frequency components has been applied, generating a Nyquist plot of impendence values in both real and imaginary axes from the measured phase difference, and presenting present the Nyquist plot at an output of the oscilloscope.

Example 12 is a method according to Example 11, further comprising:

applying at least two different loads to the UUT, measuring an amplitude ratio and phase difference between a voltage and a current of the UUT at a plurality of frequencies after the single burst of frequency components has been applied for at least two different load values applied to the UUT, generating a Nyquist plot of impendence values in both real and imaginary axes from each of the at least two measured phase difference, and producing the Nyquist plots on a single image at the output of the oscilloscope.

Example 13 is a method according to any of the preceding Example methods, in which applying a plurality of frequency components comprises applying at least 20 individual frequency points spanning a specific frequency range based on qualities of the UUT.

Example 14 is a method according to Example 13, in which the frequency range spans between 0.01 Hz and 1 kHZ.

Example 15 is a method according to any of the preceding Example methods, in which measuring the amplitude ratio and phase difference at a plurality of frequencies comprises measuring the amplitude ratio and phase difference at a plurality of frequencies based on qualities of the UUT.

Example 16 is a method according to Example 15 in which the plurality of frequencies used for measuring the amplitude ratio and phase difference spans from 1 Hz to 40 MHz.

Example 17 is a method according to any of the preceding Example methods, further comprising generating a gain plot and a phase plot of the measured amplitude and phase difference between the voltage and the current of the UUT at the plurality of frequencies, and presenting the gain plot and the phase plot on the output of the oscilloscope.

Example 18 is a method according to any of the preceding Example methods, further comprising determining a state of charge of the UUT by model fitting the Nyquist plot against a plurality of Nyquist plots of other UUTs having known states of charge, at least two of the plurality of Nyquist plots having different input voltages and temperature conditions than others in the plurality of Nyquist plots.

Example 19 is a method according to any of the preceding Example methods, further comprising generating and outputting scalar values representing one or more zones of the Nyquist plot.

Example 20 is a method according to Example 19, in which the scalar values include values for one or more of bulk resistance, solid electrolyte interface, charge transfer, and Warburg impedance.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A testing system for performing Electrochemical Impedance Spectroscopy on a Unit Under Test (UUT), the system comprising:
a function generator configured to apply a plurality of frequency components combined in a single burst or broadband stimulus to the UUT; and
an oscilloscope having one or more processors configured to:
measure an amplitude ratio and phase difference between a voltage and a current of the UUT at a plurality of frequencies after the single burst or broadband stimulus of frequency components has been applied,
generate a Nyquist plot of impendence values in both real and imaginary axes from the measured phase difference, and
present the Nyquist plot at an output of the oscilloscope.

2. The testing system according to claim 1, further comprising a load-varying device configured to apply at least two different loads to the UUT, and in which the one or more processors of the oscilloscope is further configured to:
measure an amplitude ratio and phase difference between a voltage and a current of the UUT at a plurality of frequencies after the single burst of frequency components has been applied for at least two different load values applied to the UUT,
generate a Nyquist plot of impendence values in both real and imaginary axes from each of the at least two measured phase difference, and
produce the Nyquist plots on a single image at the output of the oscilloscope.

3. The testing system according to claim 1, in which the plurality of frequency components in the single burst comprises at least 20 individual frequency points spanning a specific frequency range based on qualities of the UUT.

4. The testing system according to claim 3, in which the frequency range spans between 0.01 Hz and 1 kHZ.

5. The testing system according to claim 1, in which the plurality of frequencies used for measuring the amplitude ratio and phase difference is based on qualities of the UUT.

6. The testing system according to claim 5, in which the plurality of frequencies used for measuring the amplitude ratio and phase difference spans from 1 Hz to 40 MHz.

7. The testing system according to claim 1, in which the one or more processors of the oscilloscope are structured to:
generate a gain plot and a phase plot of the measured amplitude and phase difference between the voltage and the current of the UUT at the plurality of frequencies; and
present the gain plot and the phase plot on the output of the oscilloscope.

8. The testing system according to claim 1, further comprising determining a state of charge of the UUT by model fitting the Nyquist plot against a plurality of Nyquist plots of other UUTs having known states of charge, at least two of the plurality of Nyquist plots having different input voltages and temperature conditions than others in the plurality of Nyquist plots.

9. The testing system according to claim 1, in which the one or more processors of the oscilloscope are structured to output scalar values representing one or more zones of the Nyquist plot.

10. The testing system according to claim 9, in which the scalar values include values for one or more of bulk resistance, solid electrolyte interface, charge transfer, and Warburg impedance.

11. A method for performing Electrochemical Impedance Spectroscopy on a Unit Under Test (UUT), the method comprising:
applying a plurality of frequency components combined in a single burst or broadband stimulus to the UUT;
measuring an amplitude ratio and phase difference between a voltage and a current of the UUT at a plurality of frequencies after the single burst or broadband stimulus of frequency components has been applied;
generating a Nyquist plot of impendence values in both real and imaginary axes from the measured phase difference; and
presenting present the Nyquist plot at an output of the oscilloscope.

12. The method according to claim 11, further comprising:
applying at least two different loads to the UUT;
measuring an amplitude ratio and phase difference between a voltage and a current of the UUT at a plurality of frequencies after the single burst of frequency components has been applied for at least two different load values applied to the UUT;
generating a Nyquist plot of impendence values in both real and imaginary axes from each of the at least two measured phase difference; and
producing the Nyquist plots on a single image at the output of the oscilloscope.

13. The method according to claim 11, in which applying a plurality of frequency components comprises applying at least 20 individual frequency points spanning a specific frequency range based on qualities of the UUT.

14. The method according to claim 13, in which the frequency range spans between 0.01 Hz and 1 kHZ.

15. The method according to claim 11, in which measuring the amplitude ratio and phase difference at a plurality of frequencies comprises measuring the amplitude ratio and phase difference at a plurality of frequencies based on qualities of the UUT.

16. The method according to claim 15, in which the plurality of frequencies used for measuring the amplitude ratio and phase difference spans from 1 Hz to 40 MHz.

17. The method according to claim 11, further comprising:
generating a gain plot and a phase plot of the measured amplitude and phase difference between the voltage and the current of the UUT at the plurality of frequencies; and
presenting the gain plot and the phase plot on the output of the oscilloscope.

18. The method according to claim 11, further comprising:
determining a state of charge of the UUT by model fitting the Nyquist plot against a plurality of Nyquist plots of other UUTs having known states of charge, at least two of the plurality of Nyquist plots having different input voltages and temperature conditions than others in the plurality of Nyquist plots.

19. The method according to claim 11, further comprising generating and outputting scalar values representing one or more zones of the Nyquist plot.

20. The method according to claim 19, in which the scalar values include values for one or more of bulk resistance, solid electrolyte interface, charge transfer, and Warburg impedance.
